(19) United States
(12) Patent Application Publication
(10) Pub. No.: US 2008/0138915 A1
(43) Pub. Date: Jun. 12, 2008

(54) METHOD OF FABRICATING SEMICONDUCTOR DEVICE

(76) Inventor: Hideki OGUMA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/940,025

(22) Filed: Nov. 14, 2007

(30) Foreign Application Priority Data
Nov. 15, 2006 (JP) 2006-309468

(51) Int. Cl. H01L 21/66

(52) U.S. Cl. 438/8; 257/E21.53

(57) ABSTRACT

A method of fabricating a semiconductor device according to an embodiment of the present invention includes: forming through a first material film a second material film above a semiconductor substrate; patterning the second material film to have a predetermined pattern; trimming a width of the second material film thus patterned by performing etching; transferring a pattern of the second material film having the trimmed width on the first material film by etching the first material film; measuring a width of the first material film thus etched; and adjusting the width of the first material film to a predetermined width based on the width of the first material film thus measured.

### CROSS-REFERENCE TO RELATED APPLICATIONS

This application is based upon and claims the benefit of priority from prior Japanese Patent Application No. 2006-309468, filed on Nov. 15, 2006, the entire contents of which are incorporated herein by reference.

### BACKGROUND OF THE INVENTION

The present invention relates to a method of fabricating a semiconductor device by utilizing a suitable etching method.

Along with scale down of the recent semiconductor elements, formation of a fine pattern having the critical size or less obtained by utilizing the lithography method has been required. Also, with such scale down, although not having become conventionally a problem so much, an influence of a dispersion in sizes of the semiconductor elements among wafers becomes large. Thus, suppressing this dispersion in sizes of the semiconductor elements among the wafers is required for stabilization of the characteristics of the semiconductor element.

Such a dispersion in sizes is roughly classified into a dispersion in a size of a resist formed by utilizing the lithography method, and a dispersion in a size of an etching object in an etching process.

For example, in the case where a gate electrode is formed, after a gate insulating film, and a polycrystalline silicon film becoming a gate electrode are deposited in order on a semiconductor substrate, a resist pattern is formed on the polycrystalline silicon film at the critical size of the lithography method. The size of each resist in the resist pattern is trimmed by performing dry etching processing, and the polycrystalline silicon film is etched so that the resulting resist pattern is transferred on the polycrystalline silicon film, thereby forming the gate electrode.

In such a process, the resist pattern is formed at the dispersion in the range of about 5 to about 10 nm by utilizing the lithography method, and also is trimmed at the dispersion of several nanometers by performing dry etching processing. As a result, the size of the resulting gate electrode has a dispersion of 10 nm or more deviating from a desired size.

On the other hand, a technique for measuring a scanning electron microscope (SEM) waveform about a resist pattern formed by utilizing the lithography method, comparing the resulting waveform with a reference waveform obtained from an element, and reflecting the comparison results in etching conditions, thereby suppressing a size dispersion among lots is known as a conventional method of fabricating a semiconductor device. This technique, for example, is described in Japanese Patent KOKAI No. 2001-143982.

However, according to the conventional method of fabricating a semiconductor device, although the dispersion due to the utilization of the lithography method is absorbed to unify the sizes, up to the dispersion due to a fluctuation in the etching process cannot be suppressed.

### BRIEF SUMMARY OF THE INVENTION

A method of fabricating a semiconductor device according to an embodiment of the present invention includes:

forming through a first material film a second material film above a semiconductor substrate;

patterning the second material film to have a predetermined pattern;

trimming a width of the second material film thus patterned by performing etching;

transferring a pattern of the second material film having the trimmed width on the first material film by etching the first material film;

measuring a width of the first material film thus etched; and

adjusting the width of the first material film to a predetermined width based on the width of the first material film thus measured.

A method of fabricating a semiconductor device according to another embodiment of the present invention includes:

forming a gate insulating film, a gate electrode material film, an on-gate insulating film, and a resist in order on a semiconductor substrate;

patterning the resist to have a predetermined pattern by utilizing a lithography method;

trimming a width of the resist thus patterned by performing etching;

etching the on-gate insulating film by using the resist having the trimmed width as a mask;

peeling off the resist, and etching the gate electrode material film by using the on-gate insulating film as a mask;

measuring a width of the gate electrode material film thus etched; and

adjusting the width of the gate electrode material film to a predetermined gate length based on the width of the gate electrode material film thus measured, thereby forming a gate electrode.

A method of fabricating a semiconductor device according to still another embodiment of the present invention includes:

forming a first mask material becoming an etching mask for a semiconductor substrate, a second mask material becoming an etching mask for the first mask material, and a resist in order above the semiconductor substrate;

patterning the resist to have a predetermined pattern by utilizing a lithography method;

etching the second mask material by using the resist thus patterned as a mask;

peeling off the resist, and measuring a width of the second mask material thus etched;

adjusting the width of the second mask material to a predetermined width based on the width of the second mask material thus measured; and

etching the first mask material by using the second mask material having the adjusted width as a mask.

### BRIEF DESCRIPTION OF THE DRAWING

FIGS. 1A to 1J are respectively cross sectional views showing processes for fabricating a semiconductor device according to a first embodiment of the present invention; and

FIGS. 2A to 2K are respectively cross sectional views showing processes for fabricating a semiconductor device according to a second embodiment of the present invention.

### DETAILED DESCRIPTION OF THE INVENTION

### First Embodiment

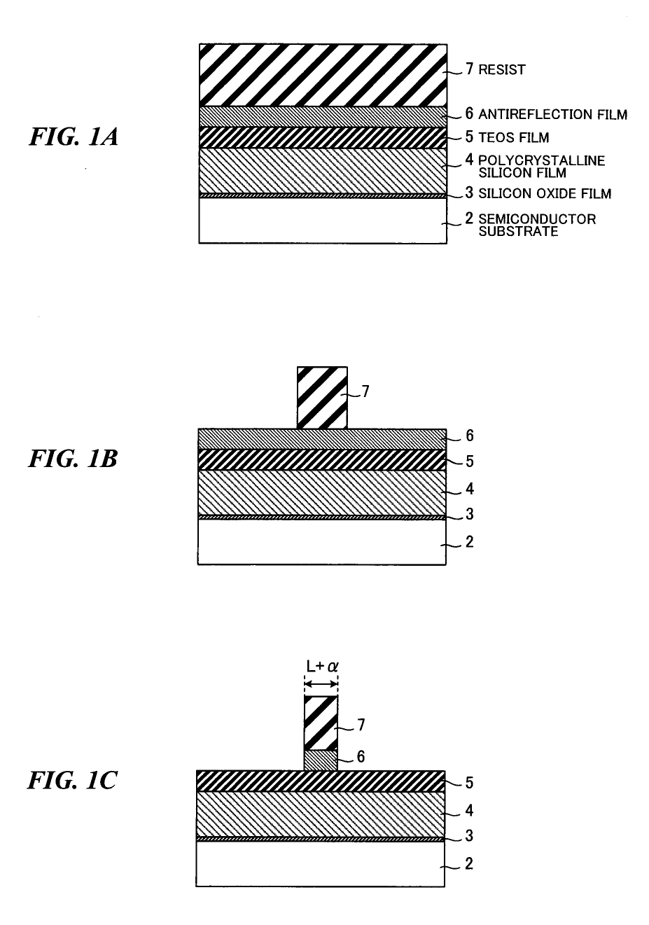

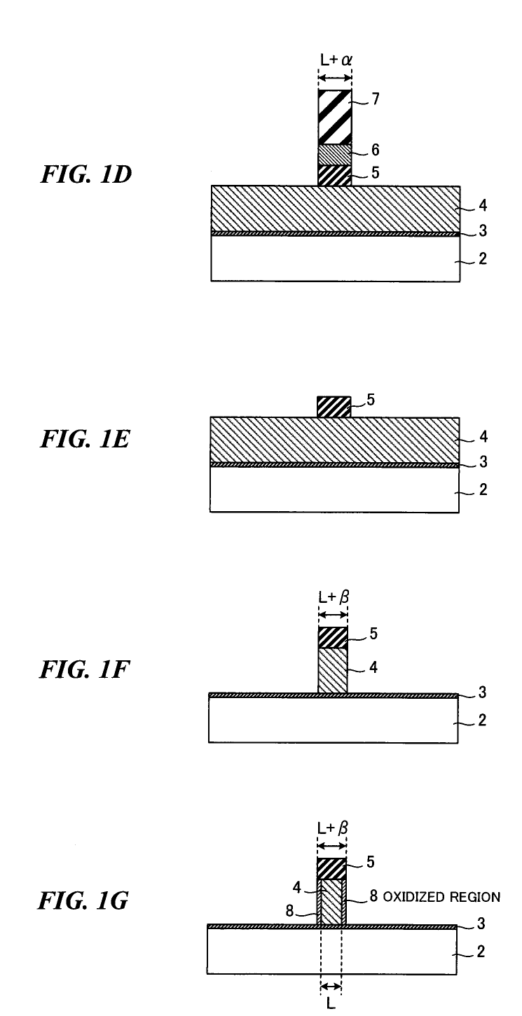

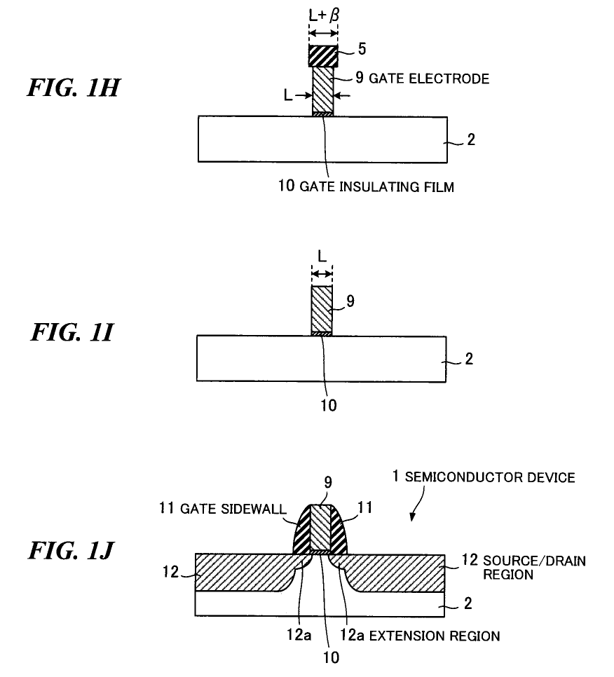

FIGS. 1A to 1J are respectively cross sectional views showing processes for fabricating a semiconductor device according to a first embodiment of the present invention.

Firstly, as shown in FIG. 1A, a silicon oxide film 3, for example, having a thickness of 1.2 nm, a polycrystalline silicon film 4, for example, having a thickness of 120 nm, and a tetraethoxysilane (TEOS) film 5, for example, having a thickness of 50 nm are formed in order on a semiconductor substrate 2 made of single crystal silicon or the like. Also, an antireflection film 6, and a resist 7 are formed in order on the TEOS film 5 by using a coater or the like.

The silicon oxide film 3 is a film becoming a gate insulating film 10 having a predetermined pattern in a later process. However, a film made of a high-dielectric material such as an Hf compound or a Zr compound may also be used instead of using the silicon oxide film 3. In addition, the polycrystalline silicon film 4 is a film becoming a gate electrode 9 in a later process. However, a metallic film, a laminated film thereof, or the like may also be used instead of using the polycrystalline silicon film 4.

In addition, for example, an insulating film, such as boro-silicate glass (BSG) film, a boro-phospho-silicate glass (BPSG) film, or a silicon nitride film, made of a material with which the polycrystalline silicon film 4 underlying the insulating film can be etched at a high selectivity may also be used instead of using the TEOS film 5.

Next, as shown in FIG. 1B, the resist 7 is patterned by utilizing a lithography method. Here, the resist 7 thus patterned serves as an etching mask when the TEOS film 5 is patterned. The resist 7 is processed to have a critical width (for example, 70 nm which is larger than a desired gate length of the gate electrode 9) which the resist 7 can be patterned to have as far as it goes by utilizing the lithography method. However, the patterned resist 7 has a dispersion in a size due to utilization of the lithography method.

Next, as shown in FIG. 1C, a width of the resist 7 is trimmed in a trim step. The trim step is carried out by utilizing a dry etching method, for example, using a gas obtained by mixing O₂ with HBr, Cl, CF₄ or the like as an etchant. When the gate electrode having a width (gate length) L is finally formed, the width of the trimmed resist 7 is set at (L+α) in the trim step. Here, α, for example, is 6 nm and is larger than a value obtained by adding a dispersion width in a size of the resist 7 due to the utilization of the lithography method and the carrying out of the trim step, and a dispersion width in amounts of TEOS film 5 and polycrystalline silicon film 4 etched for formation of the gate electrode 9 in a later process to each other. It is noted that as shown in the figure, in the trim step, the antireflection film 6 is also selectively etched to have approximately the same width as that of the resist 7.

Next, as shown in FIG. 1D, the TEOS film 5 is patterned by using the resist 7 as a mask by performing suitable dry etching processing.

Next, as shown in FIG. 1E, the resist 7 and the antireflection film 6 are peeled off by performing ashing.

Next, as shown in FIG. 1F, the polycrystalline silicon film 4 is patterned by using the TEOS film 5 as a mask by performing suitable dry etching processing, thereby transferring the pattern of the resist 7 formed to have the width (L+α) onto the polycrystalline silicon film 4. However, the width of the polycrystalline silicon film 4 slightly deviated from (L+α) due to the dispersion in the amount of polycrystalline silicon film 4 etched during the patterning. A width of the polycrystalline silicon film 4 at this time is expressed by (L+β).

After completion of the patterning, the width (L+β) of the polycrystalline silicon film 4 is measured by using a critical dimension SEM (CD-SEM). In this stage, the width of the polycrystalline silicon film 4 is β larger than the desired width L.

Next, as shown in FIG. 1G, both side surfaces of the polycrystalline silicon film 4 are oxidized in a thermal oxidation process, thereby forming an oxidized region 8. At this time, a depth of the oxidized region 8 vertical to its surface is β/2, and a width of an unoxidized region of the polycrystalline silicon film 4 is L. The depth of the oxidized region 8 from its surface, for example, can be adjusted depending on a period of time required to carry out the thermal oxidation. Also, a dispersion in the depth of the oxidized region 8 is smaller than that in the amount of polycrystalline silicon film 4 etched when the polycrystalline silicon film 4 is formed in the patterning process.

Next, as shown in FIG. 1H, the oxidized region 8 is removed by performing suitable wet etching processing using a dilute hydrofluoric acid treatment or the like. As a result, the polycrystalline silicon film 4 becomes the gate electrode 9 having a gate length L. In addition, the silicon oxide film 3 other than a portion thereof just underlying the gate electrode 9 is simultaneously removed by performing the dilute hydrofluoric acid treatment, thereby forming a pattern of the gate insulating film 10.

Moreover, as shown in FIG. 1I, the TEOS film 5 overlying the gate electrode 9 can also be perfectly removed by performing the dilute hydrofluoric acid treatment in this stage. It is noted that when a silicon nitride film is used instead of using the TEOS film 5, for example, the silicon nitride film can be removed by performing suitable wet etching processing using a hot phosphoric acid.

Next, as shown in FIG. 1J, a gate sidewall 11 made of an insulating material is formed on both side surfaces of the gate electrode 9, and a source/drain region 12 including an extension region 12a is formed in the vicinity of the surface of the semiconductor substrate 2. After that, while not illustrated in the figure, an interlayer insulating film, contacts, wirings, and the like are formed, thereby fabricating a semiconductor device 1.

According to the first embodiment of the present invention, the polycrystalline silicon film 4 is patterned so as to have the width slightly larger than desired one in consideration of the influence of the dispersion in the size of the resist 7 due to the utilization of the lithography method and the carrying out of the trim step, and the dispersion in the amounts of TEOS film 5 and polycrystalline silicon film 4 etched. After that, the width of the polycrystalline silicon 4 is measured by using the CD-SEM, and the oxidized region 8 is formed and is then removed, thereby making it possible to precisely form the gate electrode 9 having the desired gate length.

It is noted that instead of carrying out the process for forming the oxidized region 8 and the process for removing the oxidized region 8, the width of the polycrystalline silicon film 4 may be adjusted by performing suitable wet etching processing.

### Second Embodiment

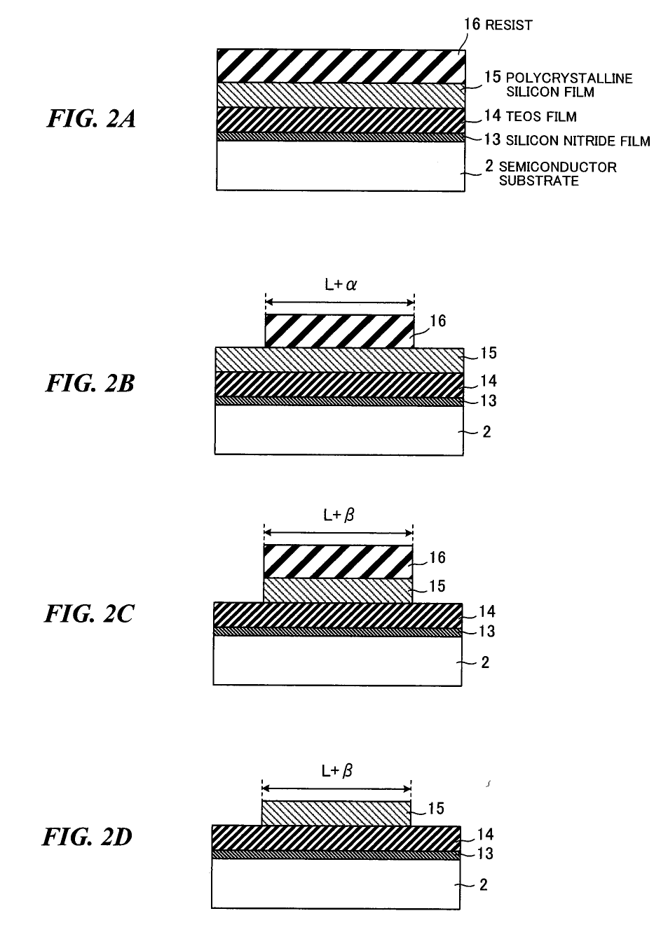

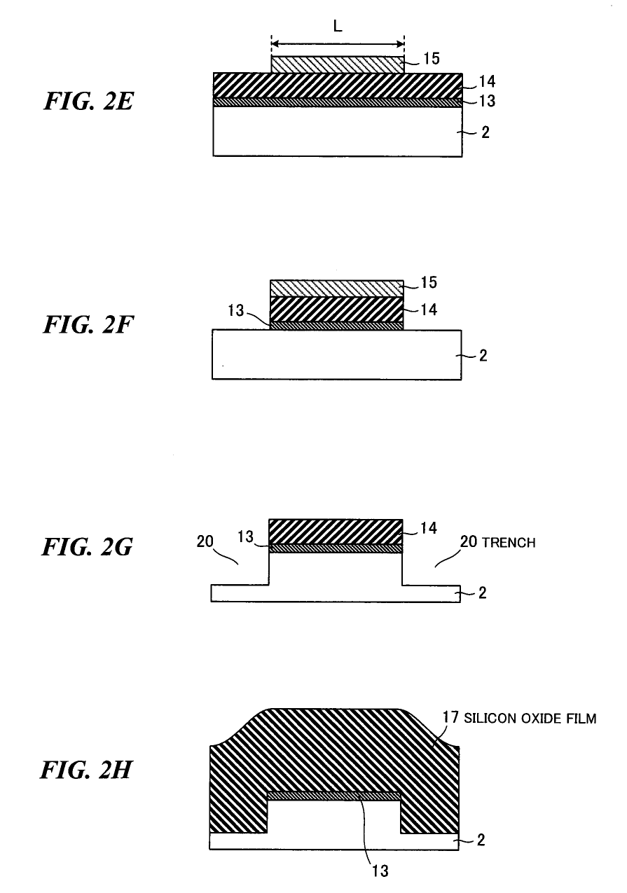

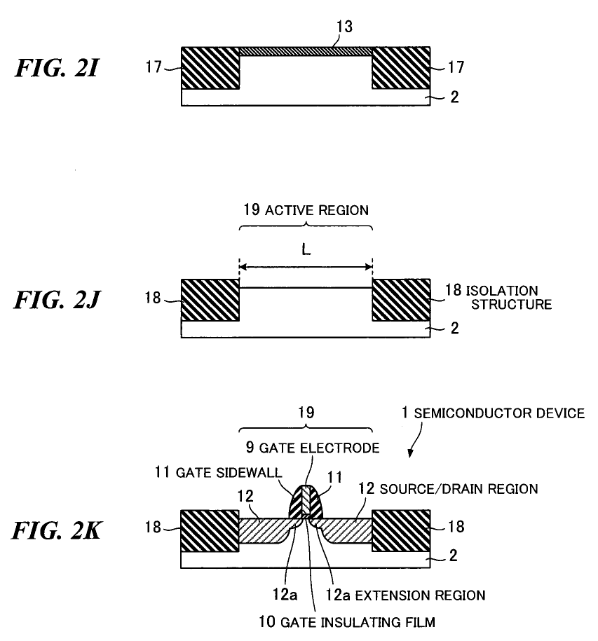

FIGS. 2A to 2K are respectively cross sectional views showing processes for fabricating a semiconductor device according to a second embodiment of the present invention.

Firstly, as shown in FIG. 2A, a silicon nitride film 13, for example, having a thickness of 100 nm, a TEOS film 14, for example, having a thickness of 150 nm, a polycrystalline silicon film 15, for example, having a thickness of 100 nm, and a resist 16 is formed in order on a semiconductor substrate 2 made of single crystal silicon or the like by utilizing an LPCVD process.

It is noted that any other suitable film made of a material showing a high etching selectivity with respect to each of the TEOS film 14 and the resist 16 may also be used instead of using the polycrystalline silicon film 15.

In addition, any other suitable film made of a material showing a high etching selectivity with respect to silicon may also be used instead of using the TEOS film 14. Moreover, the silicon nitride film 13 which is thickly formed may also be used without using the TEOS film 14.

Next, as shown in FIG. 2B, the resist 16 is patterned by utilizing the lithography method. Here, the polycrystalline silicon film 15 is a film which serves as a mask when the TEOS film 14 is selectively etched. The patterned resist 16 serves as a mask when the polycrystalline silicon 15 is selectively etched. Eventually, when a width of an active region (a region defined between adjacent isolation regions 18) 19 is set at L, a width of the patterned resist 16 is set at (L+α). Here, α, for example, is 8 nm and is larger than a value obtained by adding a dispersion width in a size of the resist 16 due to the utilization of the lithography method, and a dispersion width in an amount of polycrystalline silicon film 15 etched when the polycrystalline silicon film 15 is patterned in a later process to each other.

Next, as shown in FIG. 2C, the polycrystalline silicon film 15 is patterned by using the resist 16 as a mask by performing suitable dry etching processing. The performing of the patterning of the polycrystalline silicon film 15 results in that a width of the polycrystalline silicon film 15 slightly deviates from (L+α) due to the dispersion in the amount of polycrystalline silicon film 15 etched. A width of the polycrystalline silicon film 15 at this time is expressed by (L+β).

Next, as shown in FIG. 2D, the patterned resist 16 is peeled off by performing the ashing. After completion of the peeling-off of the resist 16, the width (L+β) of the polycrystalline silicon 15 is measured by using the CD-SEM. In this stage, the width of the polycrystalline silicon 15 is β larger than the desired width L.

Next, as shown in FIG. 2E, the polycrystalline silicon film 15 is removed vertically to its region at a depth β/2 from its original surface by, for example, performing alkali system wet etching processing using choline, thereby trimming the width of the polycrystalline silicon film 15 to L. Here, a depth of a portion, of the polycrystalline silicon film 15, to be removed from its original surface, for example, can be adjusted depending on a period of time required to perform the wet etching processing. Also, a dispersion in the depth of the removed portion of the polycrystalline silicon film 15 is less than that in the amount of semiconductor substrate 2 etched when the semiconductor substrate 2 is selectively etched. It is noted that when after completion of the etching for the TEOS film 14 and the silicon nitride film 13 in a later process, each of widths of the TEOS film 14 and silicon nitride film 13 thus etched is adjusted to L without adjusting the width of the polycrystalline silicon film 15 in this stage, the polycrystalline silicon film 15 which is patterned to have the width (L+β) necessarily becomes a mask. This leads to that it is difficult to transfer the pattern having the width L on the semiconductor substrate 2.

Next, as shown in FIG. 2F, the TEOS film 14 and the silicon nitride film 13 are dry-etched by using the polycrystalline silicon film 15 as a mask.

Next, as shown in FIG. 2G, the semiconductor substrate 2 is selectively etched by using both the polycrystalline silicon film 15 and the TEOS film 14 as a mask, thereby forming a trench 20, for example, having a depth of 300 nm. During this etching process, the polycrystalline silicon film 15 is consumed to expose the TEOS film 14.

Next, as shown in FIG. 2H, after the TEOS film 14 is peeled off by performing a dilute hydrofluoric acid treatment, a silicon oxide film 17 is deposited over the trench 20 of the semiconductor substrate 2, and the silicon nitride film 13 by utilizing a CVD method.

Next, as shown in FIG. 2I, chemical mechanical polishing (CMP) is carried out by using the silicon nitride film 13 as a stopper, thereby flattening the silicon oxide film 17.

Next, as shown in FIG. 2J, the silicon nitride film 13 is peeled off by using a hot phosphoric acid. As a result, the silicon oxide film 17 becomes the isolation region 18, and the active region 19 having a width L in the gate length direction is defined between the adjacent isolation regions 18.

Next, as shown in FIG. 2K, the gate electrode 9 is formed on the active region 19 of the semiconductor substrate 2 through the gate insulating film 10. Also, the gate sidewall 11 made of the insulating material is formed on the both side surfaces of the gate electrode 9, and the source/drain region 12 including the extension region 12a is formed in the vicinity of the surface of the semiconductor substrate 2. After that, while not illustrated in the figure, the interlayer insulating film, the contacts, the wirings, and the like are formed, thereby fabricating the semiconductor device 1.

According to the second embodiment of the present invention, the resist 16 is patterned so as to have the width slightly larger than desired one in consideration of the influence of the dispersion in the size of the resist 16 due to the utilization of the lithography method, and the dispersion in the amount of polycrystalline silicon film 15 etched. After that, the width of the polycrystalline silicon film 15 is measured by using the CD-SEM, and is adjusted by performing the wet etching processing. As a result, it is possible to precisely fabricate the semiconductor device 1 including the active region 19 having approximately the desired width.

### Other Embodiments

It should be noted that the present invention is not limited to the embodiments described above, and thus the various changes can be implemented without departing from the gist of the invention.

For example, the present invention is not limited to the formation of the gate electrode and the active region shown in each of the embodiments described above, and can be applied to formation of the various members using the suitable etching method.

In addition, the constituent elements of the embodiments described above can be arbitrarily combined with one another without departing from the gist of the invention.

What is claimed is:

1. A method of fabricating a semiconductor device, comprising:
forming through a first material film a second material film above a semiconductor substrate;
patterning the second material film to have a predetermined pattern;
trimming a width of the second material film thus patterned by performing etching;
transferring a pattern of the second material film having the trimmed width on the first material film by etching the first material film;
measuring a width of the first material film thus etched; and
adjusting the width of the first material film to a predetermined width based on the width of the first material film thus measured.

2. The method of fabricating a semiconductor device according to claim 1, wherein the adjusting of the width of the first material film comprises:
oxidizing a side surface of the first material film to a predetermined depth based on the measured width of the first material film; and
removing an oxidized portion of the first material film.

3. The method of fabricating a semiconductor device according to claim 2, wherein the removal of the oxidized portion of the first material film is carried out by performing wet etching.

4. The method of fabricating a semiconductor device according to claim 1, wherein the second material film is formed from a resist, and is patterned to have a critical width in patterning by a lithography method.

5. The method of fabricating a semiconductor device according to claim 4, wherein a width of the second material film after the trimming by the etching is larger than that obtained by adding a dispersion width in a size due to the patterning for the second material film and the etching for trimming the width of the second material film, and a dispersion width in a size due to the etching for the first material film to the predetermined width of the first material film obtained in the adjustment process.

6. The method of fabricating a semiconductor device according to claim 1, wherein the width of the first material film is measured by using a CD-SEM.

7. A method of fabricating a semiconductor device, comprising:
forming a gate insulating film, a gate electrode material film, an on-gate insulating film, and a resist in order on a semiconductor substrate;
patterning the resist to have a predetermined pattern by utilizing a lithography method;
trimming a width of the resist thus patterned by performing etching;
etching the on-gate insulating film by using the resist having the trimmed width as a mask;
peeling off the resist, and etching the gate electrode material film by using the on-gate insulating film as a mask;
measuring a width of the gate electrode material film thus etched; and
adjusting the width of the gate electrode material film to a predetermined gate length based on the width of the gate electrode material film thus measured, thereby forming a gate electrode.

8. The method of fabricating a semiconductor device according to claim 7, wherein the adjusting of the width of the gate electrode material film comprises:
oxidizing a side surface of the gate electrode material film to a predetermined depth; and
removing an oxidized portion of the gate electrode material film.

9. The method of fabricating a semiconductor device according to claim 8, wherein the removal of the oxidized portion of the gate electrode material film is carried out by performing wet etching.

10. The method of fabricating a semiconductor device according to claim 7, wherein a width of the resist after the trimming by the etching is larger than that obtained by adding a dispersion width in a size due to the patterning for the resist and the etching for trimming the width of the resist, and a dispersion width in a size due to the etching for the on-gate insulating film and the gate electrode material film to the predetermined gate length.

11. The method of fabricating a semiconductor device according to claim 7, wherein the width of the gate electrode material film is measured by using a CD-SEM.

12. The method of fabricating a semiconductor device according to claim 7, wherein the width of the resist is trimmed by performing dry etching.

13. The method of fabricating a semiconductor device according to claim 7, wherein the on-gate insulating film is etched by performing dry etching.

14. The method of fabricating a semiconductor device according to claim 7, wherein the resist is formed on the on-gate insulating film through the antireflection film;
the antireflection film is processed to have approximately the same width as that of the resist concurrently with the trimming of the width of the resist by the etching; and
the antireflection film thus processed is peeled off concurrently with the peeling-off of the resist.

15. A method of fabricating a semiconductor device, comprising:
forming a first mask material becoming an etching mask for a semiconductor substrate, a second mask material becoming an etching mask for the first mask material, and a resist in order above the semiconductor substrate;
patterning the resist to have a predetermined pattern by utilizing a lithography method;
etching the second mask material by using the resist thus patterned as a mask;
peeling off the resist, and measuring a width of the second mask material thus etched;
adjusting the width of the second mask material to a predetermined width based on the width of the second mask material thus measured; and
etching the first mask material by using the second mask material having the adjusted width as a mask.

16. The method of fabricating a semiconductor device according to claim 15, further comprising:
etching the semiconductor substrate by using the first mask material as a mask to form a trench after the first mask material is etched;
depositing an insulating film in the trench of the semiconductor substrate; and
flattening the insulating film, thereby forming an isolation structure in the trench.

17. The method of fabricating a semiconductor device according to claim 15, wherein a width of the resist patterned to have the predetermined pattern is larger than that obtained by adding a dispersion width in a size due to the patterning for the resist and a dispersion width in a size due to the etching for the second mask material to a width of the etched first mask material.

18. The method of fabricating a semiconductor device according to claim 15, wherein the width of the second mask material is measured by using a CD-SEM.

19. The method of fabricating a semiconductor device according to claim 15, wherein the width of the second mask material is adjusted by performing wet etching.

20. The method of fabricating a semiconductor device according to claim 16, wherein the first mask material is formed on the semiconductor substrate through another insulating film;
after the first material is etched, the another insulating film is etched by using the second mask material having the adjusted width as a mask; and
the insulating film is flattened by using an upper surface of the another insulating film as a stopper.
